(19) United States
(12) Patent Application Publication
(10) Pub. No.: US 2007/0290675 A1
(43) Pub. Date: Dec. 20, 2007

(54) Circuit for Supplying Electrical Energy to Measuring Instrument

(76) Inventors: Siegfried Birkle, Hochstadt (DE); Stefan Hain, Effeltrich (DE)

Correspondence Address: STAAS & HALSEY LLP, SUITE 700, 1201 NEW YORK AVENUE, N.W., WASHINGTON, DC, 20005, US

(21) Appl. No.: 11/661,038

(22) PCT Filed: Aug. 12, 2005
(86) PCT No.: PCT/EP05/53971

§ 371 Date: Feb. 26, 2007

(30) Foreign Application Priority Data
Aug. 24, 2004 (DE) 10 2004 041 091.7
Jul. 18, 2005 (DE) 10 2005 033 451.2

(51) Int. Cl. G01R 15/18; G01R 15/14

(52) U.S. Cl. 324/127

(57) ABSTRACT

An electric measuring device is supplied with electric energy at a high-voltage potential by a circuit that includes at least one first transformer on the ground potential side. The first transformer has a primary side, to which a generator is attached to generate a feed signal that supplies energy, and a symmetrically sub-divided secondary side with a division point connected to the ground potential. The circuit also has at least one second transformer on the high-voltage potential side with a symmetrically sub-divided primary side, whose division point is connected to the high-voltage potential and a secondary side, to which the measuring device can be connected for the energy supply. In addition, at least one symmetrically configured transmission element attenuates the potential and is equipped with two parallel sub-branches running between the secondary side of the first transformer and the primary side of the second transformer. To divide the voltage, each respective transmission element includes at least two voltage dividers, each having an intermediate nodal point. The respective transmission element can be connected to the measuring device via both nodal points by a respective line to measure the voltage.

### CROSS REFERENCE TO RELATED APPLICATIONS

This application is based on and hereby claims priority to German Application No. 10 2004 041 091.7 filed on Aug. 24, 2004 and German Application No. 10 2005 033 451.2 filed on Jul. 18, 2005, the contents of which are hereby incorporated by reference.

### BACKGROUND

Described below is a circuit for supplying electrical energy to an electrical measuring instrument arranged at a high voltage potential.

For the purposes of protection and measurement, it is necessary in high voltage installations to measure the current in the conductor located at a high voltage potential. For reasons of costs, and to further noise-free data transmission, it has proved to be advantageous to digitize the signal of a current transformer while still at a high voltage potential, and to transmit the measuring signal with the aid of optical fibers for the purpose of further processing at ground potential. However, this requires supplying auxiliary power to the electronics located at a high voltage potential. It is likewise necessary for the purposes of protection and measurement to measure the electric voltage of the conductor. At present, separate current and voltage transformers are set up to this end, in which case costs and outlay on installation accrue for two items of equipment.

“Sensors and Actuators A”, volumes 25 to 27 (1991), pages 475 to 480 describes an arrangement in the case of which light from a light source, here a laser diode, is transmitted to a photoelectric transducer, and is converted there into electrical energy. The latter serves to supply a sensor. The measured data of the sensor are likewise transmitted optically via an optical fiber. However, because of the special components used, in particular the high power laser, the photoelectric transducer and also the optical plug-in connectors, this supply system entails a not inconsiderable outlay and costs.

In the arrangement specified in DE 910 925, a radio-frequency signal is transmitted by capacitive components in order to control the drive for gas and steam discharge paths. A first capacitive sub-branch is provided for the forward direction, and a second capacitive sub-branch is provided for the backward direction. The radiofrequency signal is, however, not used for supplying power but, in fact, for controlling an ignition circuit which is arranged at a high voltage potential.

DE 29 11 476 A1 specifies an arrangement that uses two capacitor chains in order to transmit auxiliary power capacitively to a high voltage potential. At the same time, a capacitive divider for voltage measurement is constructed at the capacitor foot. The task of the parallel inductors is to relieve the high frequency generator by providing reactive power, and to compensate insulation differences occurring between neighboring capacitors. However, the arrangement is complicated to implement owing to the multiplicity of individual components required. Moreover, if the intent is to use this arrangement to detect current and voltage, it is necessary to provide two separate electronic measuring modules.

### SUMMARY

An aspect is a circuit for supplying electrical energy to a measuring instrument arranged at a high voltage potential, which ensures as simple a power supply as possible, and simultaneously enables saving of space and material.

The circuit for supplying electrical energy to an electrical measuring instrument arranged at a high voltage potential includes at least: a first transformer on the ground potential side, which has a primary side to which a generator for generating an energy-supplying feed signal is connected, and has a symmetrically subdivided secondary side whose division point is at the ground potential. Also, a second transformer is provided on the high voltage potential side, which has a symmetrically subdivided primary side whose division point is at the high voltage potential, and has a secondary side to which the measuring instrument is to be connected for the supply of energy. In addition, a symmetrically constructed potential-reducing transmission element, that has two parallel sub-branches that run between the secondary side of the first transformer and the primary side of the second transformer, has in each case for the purpose of voltage division at least two voltage dividers with an intermediate nodal point, and is connected to the measuring instrument for the purpose of voltage measurement via the two nodal points, via a respective line.

The circuit is based on the realization that when two lines which respectively conduct a balanced signal are brought together the balanced signals cancel out one another because of their opposing phase angles. Thus, the two-part transmission link formed by the two sub-branches can be used to operate a measuring instrument, arranged at a high voltage potential, with the aid of a feed signal that is generated by a generator arranged at ground potential, and at the same time to undertake a voltage measurement, in the case of which the voltage is tapped at the two sub-branches, without the voltage being disturbed by the feed signal.

It is particularly advantageous that the measuring instrument is designed for determining an electric current and an electric voltage. Consequently, all the parts of the voltage divider are located in one housing and are produced in a similar fashion. A possible sensitivity of the components to temperature is thus ideally cancelled out. In addition, there is a need for only one electronic system for acquiring measured values.

Furthermore, it is advantageous that the generator is designed with low power in such a way that an electric power of at most 100 mW can be fed to the measuring instrument by a feed signal. The circuit therefore requires no parallel inductors. Owing to a low consumption of auxiliary power by the electronic measuring system, the amplitude and frequency of the feed voltage can be kept low. It is thereby possible for the feed voltage source to supply reactive power for the capacitors with a low technical outlay. Specifically, installing the parallel inductors and making contact with them in a high voltage capacitor are complicated procedures and prevent further simplification in the production of the capacitors. In addition, apart from the capacitors no additional components in the high voltage branch are required for AC voltage applications. The capacitor can thus be produced like a conventional control capacitor that can be manufactured in large numbers.

The two sub-branches are preferably arranged closely neighboring one another. The space required for the circuit is thereby reduced. Moreover, the close spatial neighborhood of the two sub-branches prevents an emission, undesirable per se, of feed energy. The two sub-branches respectively intended for the forward or backward direction act in a similar way to a bifilar conductor arrangement in which mutual compensation is provided for the emission response.

It is advantageous that the two sub-branches are arranged next to one another in an insulator. This reduces the costs for the voltage insulation of the two sub-branches, because it is possible to use at least one common insulator housing.

In particular, the feed signal has a feed frequency of between 1 kHz and 1 MHz. An emission of feed energy can be effectively suppressed in this frequency range. Moreover, the lower limit is far enough from a system frequency that is used for public power supply facilities (DC or 50 Hz or 60 Hz), as well as sufficiently far removed from the harmonics of this system frequency which may be relevant for the purpose of measurement and evaluation, so that any influence can be precluded.

It is particularly advantageous that an additional, in particular optical, transmission link is provided for transmitting a measuring signal determined by the measuring instrument. This achieves a particularly good separation between feed signal and measuring signal.

Furthermore, it is advantageous that the at least two voltage dividers of the respective sub-branch are at least two capacitors. A voltage divider can therefore be constructed in a particularly simple and cost-effective way.

It is advantageous that the at least two voltage dividers of the respective sub-branch are at least two parallel circuits composed of at least one capacitor and at least one resistor. The circuit can therefore be used both in DC and in AC voltage installations.

### BRIEF DESCRIPTION OF THE DRAWINGS

These and other objects and advantages will become more apparent and more readily appreciated from the following description of the exemplary embodiments, although these are in no way restrictive, taken in conjunction with the accompanying drawings which are not to scale.

FIG. 1 is a circuit diagram of a circuit for supplying electrical energy to an electric current and voltage measuring instrument arranged at a high voltage potential, for use in AC voltage installations, and

FIG. 2 is a circuit diagram of a circuit for supplying electrical energy to an electric current and voltage measuring instrument arranged at a high voltage potential, for use both in DC and in AC voltage installations.

### DETAILED DESCRIPTION OF THE PREFERRED EMBODIMENT

Reference will now be made in detail to the preferred embodiments, examples of which are illustrated in the accompanying drawings, wherein like reference symbols refer to like elements throughout.

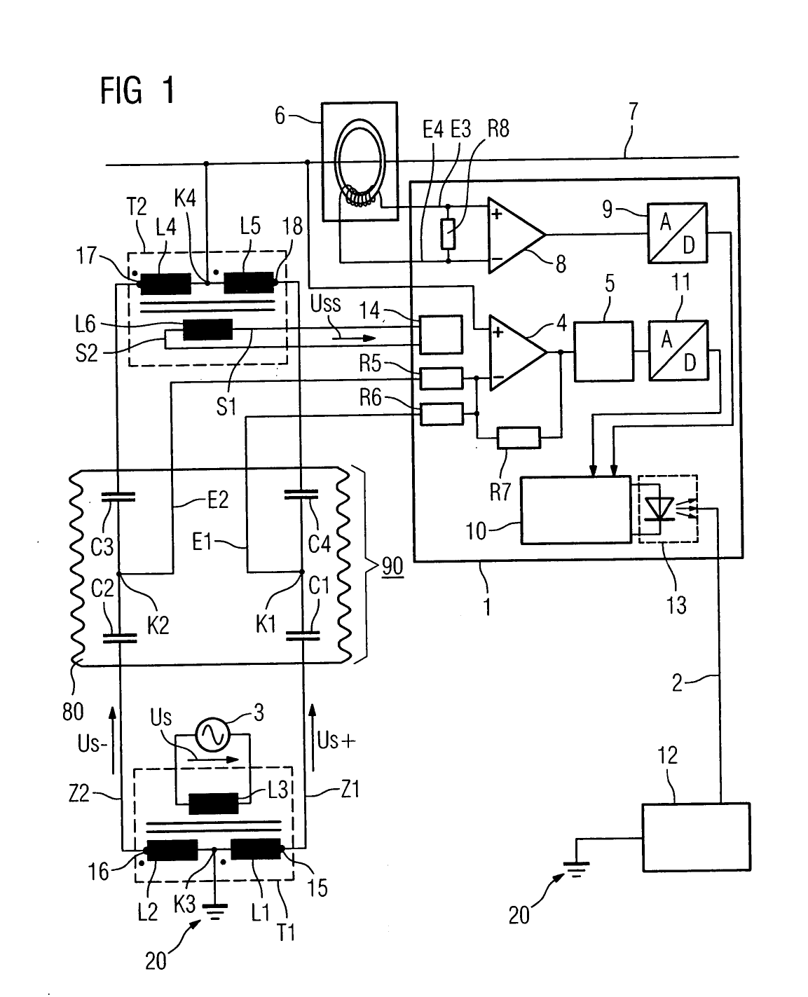

FIG. 1 illustrates an exemplary embodiment of a circuit for supplying electrical energy to an electric current and voltage measuring instrument 1 arranged at a high voltage potential. The symmetrically constructed, potential-reducing transmission element 90 of the circuit has four capacitors C1 to C4 that are provided as a voltage divider. It holds in this case for the dimensioning of the capacitors C1 to C4 that C1=C2 and C3=C4, the aim being for the capacitors C3 and C4 to have 100 times to 10 000 times the value of the capacitors C1 and C2. Thus, for example, values of 0.1 nF to 10 nF are conceivable for the capacitors C1 and C2. Consequently, the capacitors C3 and C4 must assume a value of 10 nF to 100 μF. The voltage tap for the voltage measurement is performed at a high voltage potential at the nodal points K1 and K2. The electronic measuring system of the measuring instrument 1 is likewise located at a high voltage potential and simultaneously acquires current and voltage values, digitizes these and transmits them to ground potential 20 via at least one optical fiber 2. The electronic measuring system of the measuring instrument 1 is designed to be as economical as possible in the consumption of auxiliary power, such that, in particular, 100 mW is not exceeded. The auxiliary power is supplied via two transformers T1 and T2. The transformers T1 and T2 are appropriately interconnected via their terminals 15, 16 and 17, 18 by two sub-branches Z1 and Z2. The transformer T1 includes the inductors L1, L2 and L3, and the transformer T2 includes the inductors L4, L5 and L6. The corresponding inductors L1, L2, L3 and L4, L5, L6 of the respective transformer T1 or T2 are preferably arranged on a common core and therefore closely magnetically coupled to one another.

A feed signal Us generated by the generator 3 and which can, for example, lie in a frequency range of 1 kHz to 1 MHz and may, for example, have a voltage value of 10 V to 1 kV is fed to the transformer T1 via the primary side of the transformer T1 with the inductor L3. The feed signal Us is converted into a balanced feed signal Us+ and Us− on the secondary side of the transformer T1, which has the two inductors L1 and L2. To this end, a grounded division point K3 is arranged between the two inductors L1 and L2. The second transformer T2 has a division point K4 arranged on the primary side, between the inductors L4 and L5 and which is connected to a high voltage conductor 7. The balanced feed signal Us+ and Us− fed to the primary side of the transformer T2 leads on the secondary side in the transformer T2 to a feed signal Uss. The feed signal is fed into the energy supply unit 14 of the measuring instrument 1 via two feed lines S1 and S2 connected to the secondary side of the transformer T2. The secondary side of the transformer T2 has the inductor L6 in this case.

The inductors L2 and L2 and respectively L4 and L5 are connected in series for the balanced feed signal Us+ and Us−, and therefore have a high inductance of, for example, over 1 mH. The impedance therefore lies in a range of, for example 100 Ω to 10 Ω. For the high voltage that is to be measured, which can usually lie in the frequency range of 0 Hz (DC voltage) to 500 Hz, the inductors L1 and L2 or L4 and L5 are connected in an anti-parallel fashion to their respective core and therefore have an inductance that is smaller by a factor of 10 to 1000 and can amount in this example to between 1 μH and 100 μH. This entails that a small impedance of below 1 Ω, for example, is present in the range of frequency of the high voltage to be measured. This impedance is very small in relation to the impedance of the capacitors C1 and C2, and so the voltage drop across the inductors L4 and L5 during the voltage measurement can be neglected.

As indicated in FIG. 1, the acquisition of the current value of the high voltage line 7 can be performed, for example, with the aid of an inductive current transformer 6. Other current measuring methods, such as, for example, current measurement by a shunt, are likewise conceivable. The measuring signals generated by the current transformer 6 are transmitted via two lines E3 and E4 to an operational amplifier 8 connected as a difference amplifier, the line E3 being connected to the non-inverting input of the operational amplifier 8, and the line E4 being connected to the inverting input of the operational amplifier 8. A resistor R8 via which the two lines E3 and E4 are interconnected is moreover connected in parallel with the two inputs of the operational amplifier 8. To this end, the resistor R8 has, in particular, a resistance value in the range of 10 mΩ to 100 Ω. The output of the amplifier is connected to an analog-to-digital converter 9 that digitizes the analog signals supplied by the operational amplifier 8 and passes them on to a transmission unit 10.

For the purpose of voltage measurement, the two voltages dropping across the capacitor C3 and the inductor L4, or across the capacitor C4 and the inductor L5, and tapped via the two nodal points K1 and K2 are fed via two lines E1 and E2 to the measuring instrument 1 and are added there by a further operational amplifier 4, which is connected as an adder. In this case, on the one hand the noninverting input of the operational amplifier 4 is connected to the high voltage conductor 7 and, on the other hand, the inverting input of the operational amplifier 4 is connected to the node K1 via the resistor R6, and to the node K2 via the resistor R5. Moreover, a resistor R7 connects the inverting input to the output of the operational amplifier 4. The resistance value for the resistors R5 and R6 lies, in particular, in the range of 100 Ω to 1 MΩ. A resistance value in the range of 100 Ω to 1 MΩ is also suitable for the resistor R7. Since the balanced feed signal Us+ and the balanced feed signal Us− are conducted as two oppositely phased signals in the two sub-branches Z1 and Z2, while the voltages to be fed back to the high voltage that is present are co-phasal in the two sub-branches Z1 and Z2, the oppositely phased feed signals cancel out one another at the output of the adder given an ideally balanced construction, while the measuring voltage drops are doubled. Residual feed voltages remaining owing to asymmetries in the construction can easily be removed by a lowpass filter 5, since the frequencies of the high voltage differ by approximately one order of magnitude from those of the feed signal. The output of the lowpass filter 5 is connected to an analog-to-digital converter 11 that digitizes the analog signals supplied by the lowpass filter 5 and likewise passes them on to the transmission unit 10.

The transmission unit 10 includes a light source 13, in particular a light-emitting diode, that can be used to send the digitized measured values of current and voltage by transmitting light via an optical fiber 2 to an evaluation unit 12 preferably arranged at ground potential 20.

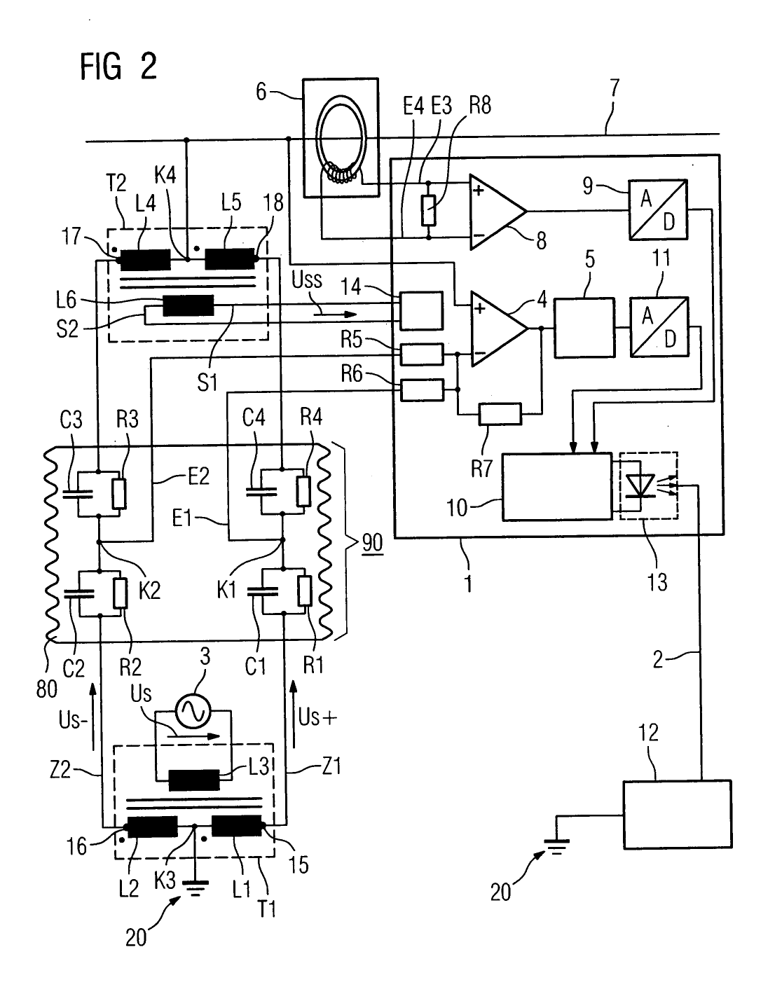

The exemplary embodiment illustrated in FIG. 2 corresponds substantially to the exemplary embodiment shown in FIG. 1. However, it is provided over and above this for use in a DC voltage installation. In this case, the capacitors C1, C2, C3 and C4 in the symmetrically constructed potential-reducing transmission element 90 are expanded by resistors R1, R2, R3 and R4 connected correspondingly in parallel, the result being a compensated voltage divider. The resistors R1 and R2 respectively have a value that is higher by a factor of 1000 than the corresponding two resistors R4 and R5 of the respective sub-branches Z1 and Z2. If the resistances of R4 and R3, in particular, are dimensioned in the kΩ range, the resistors R1 and R2 therefore have resistance values in the MΩ range. R1 and R2 are, moreover, designed, in particular, for a power of at least 10 W.

It is further to be seen in FIG. 1 and in FIG. 2 that for the purpose of high voltage insulation the transmission element 90 with the two sub-branches Z1 and Z2 arranged next to one another is accommodated in an insulator 80 including both sub-branches Z1, Z2.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-9. (canceled)

10. An electrical measuring circuit supplying electricity from a generator to an electrical measuring instrument operating at a high voltage potential, comprising:
a first transformer on a ground potential side having a primary side, connected to the generator to receive an energy-supplying feed signal, and having a symmetrically subdivided secondary side with a division point connected to ground potential;
a second transformer on a high voltage potential side having a symmetrically subdivided primary side with a division point at the high voltage potential and a secondary side to which the measuring instrument is connected to receive electrical power;
a symmetrically constructed potential-reducing transmission element having two parallel sub-branches that run between the secondary side of said first transformer and the primary side of said second transformer, and having at least two voltage dividers with an intermediate nodal point; and
two lines, connected in an electrically combined fashion from the two nodal points of said symmetrically constructed potential-reducing transmission element to the measuring instrument, providing voltage measurement between the high voltage potential and the nodal points.

11. The electrical measuring circuit as claimed in claim 10, wherein the measuring instrument determines an electric voltage and an electric current.

12. The electrical measuring circuit as claimed in claim 11, wherein the generator is a low-power generator and the energy-supplying feed signal is at most 100 mW.

13. The electrical measuring circuit as claimed in claim 12, wherein the two sub-branches in the symmetrically constructed potential-reducing transmission element are arranged in close proximity.

14. The electrical measuring circuit as claimed in claim 13, wherein the two sub-branches in the symmetrically constructed potential-reducing transmission element are substantially surrounded by an insulator.

15. The electrical measuring circuit as claimed in claim 14, wherein the energy-supplying feed signal has a frequency of between 1 kHz and 1 MHz.

16. The electrical measuring circuit as claimed in claim 15, further comprising an optical transmission link transmitting a measuring signal obtained by the electrical measuring instrument.

17. The electrical measuring circuit as claimed in claim 16, wherein each of the at least two voltage dividers is formed by at least two capacitors.

18. The electrical measuring circuit as claimed in claim 16, wherein each of the at least two voltage dividers is formed by at least two parallel circuits, each having at least one capacitor and at least one resistor.
